(19) United States
(12) Patent Application Publication
(10) Pub. No.: US 2026/0186427 A1
(43) Pub. Date: Jul. 2, 2026

(54) METHOD FOR REDUCING THE EFFECTS OF PARASITIC FORCES AND/OR MOMENTS ON THE IMAGING QUALITY OF A PROJECTION-EXPOSURE APPARATUS, AND PROJECTION-EXPOSURE APPARATUS WITH A MODULE

(71) Applicants: Carl Zeiss SMT GmbH, Oberkochen (DE); ASML NETHERLANDS B.V., Veldhoven (NL)

(72) Inventors: Luca METTENLEITER, Neresheim (DE); Matthias FETZER, Stuttgart (DE); Steffen WAIMER, Gruenkraut (DE); Maurice Willem Jozef Etiënne WIJCKMANS, Veldhoven (NL); Remco VAN DE MEERENDONK, ’s-Hertogenbosch (NL)

(21) Appl. No.: 19/548,320

(22) Filed: Feb. 24, 2026

Related U.S. Application Data
(63) Continuation of application No. PCT/EP2024/072462, filed on Aug. 8, 2024.

(30) Foreign Application Priority Data
Aug. 24, 2023 (DE) 10 2023 122 782.3

(51) Int. Cl. G03F 7/00; G02B 26/08

(52) U.S. Cl. CPC G03F 7/70833; G02B 26/0833; G03F 7/70258; G03F 7/707; G03F 7/70766; G03F 7/70991

(57) ABSTRACT

A projection-exposure apparatus (1, 101) with at least one module (40, 50) including a fluid channel (41, 51) which at least at times contains a pressurized fluid (42, 52). The fluid channel is connected to supply lines (47.1, 47.2, 57.1, 57.2) which are connected by bearing points (48.1, 48.2, 58.1, 58.2) to a supporting frame (66). The module is symmetrically formed. A related method for reducing the effect on the imaging quality of a projection-exposure apparatus that is brought about by parasitic forces (Fres) and/or moments (Mres) caused by pressure fluctuations induced by flow and/or transferred via a fluid (42, 52) and acting on a module of the projection-exposure apparatus includes determining the parasitic forces (Fres) and/or moments (Mres), defining at least two at least partially compensating forces (Fuw) and/or moments (MVTxz, MATxz), and creating the module for producing the compensating forces and/or moments.

### CROSS-REFERENCE TO RELATED APPLICATIONS

This is a Continuation of International Application PCT/EP2024/072462 which has an international filing date of Aug. 8, 2024, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2023 122 782.3 filed on Aug. 24, 2023.

### FIELD

The invention relates to a method for reducing the effects of parasitic forces and/or moments on the imaging quality of a projection exposure apparatus and to a projection exposure apparatus having an in particular symmetrical module.

### BACKGROUND

Projection exposure apparatuses must meet higher requirements for accuracy and precision from one generation to the next. Such apparatuses are used for producing extremely fine structures, in particular on semiconductor components or other microstructured component parts. The operating principle of these apparatuses is based on the production of extremely fine structures down to the nanometer scale by way of generally reducing imaging of structures on a mask, also referred to as a reticle, on an element to be structured, also referred to as a wafer, that is provided with photosensitive material. The minimum dimensions of the structures produced are directly dependent on the wavelength of the light used in the production. The light sources used in previous apparatuses have an emission wavelength in the range of 100 nm to 300 nm, in particular in the region of 193 nm, which is referred to as the DUV (Deep UltraViolet) range. Recently, by contrast, light sources having an emission wavelength in the range of a few nanometers, for example between 1 nm and 120 nm, in particular in the range of 13.5 nm, which allow a higher resolution are increasingly being used. The described wavelength range is also referred to as the EUV (Extreme UltraViolet) range.

The imaging quality of the projection exposure apparatuses is influenced in particular by how precisely their components can occupy an intended or rest position in the space. From a dynamic point of view, in order to meet these requirements, it is necessary to reduce the influence of introduced disturbances, for example in the form of mechanical oscillations, on these components, which are for example support and reference structures and/or optical modules. This applies in particular to the optical modules which comprise the optical elements used for the imaging, such as lenses or mirrors, but also to support structures for a wafer, such as a module for holding and positioning the wafer or a part of the module, such as an electrostatic mount for the wafer or for reference structures, which serve for example as a reference for the positioning of the optical elements.

The disturbance, that is to say for example a mechanical oscillation, can be split into a low-frequency component and a higher-frequency component.

When a structure of a reticle is being imaged onto a wafer, the low-frequency component causes a quasi-static deviation from an intended position of the optical element, which can result for example in a shift in the position of the imaging on the wafer.

The higher-frequency component corresponds to a mechanical oscillation, as a result of which the imaging becomes blurred, i.e. the contrast of the imaging deteriorates.

The above-mentioned disturbances can be caused for example by fluids, for example water, that flow in components of the projection exposure apparatus and are usually used for controlling the temperature, in particular for cooling.

Effective cooling requires a specific flow rate of the fluid in the cooling lines. For this purpose, a pump is usually used to generate a pressure p which prevails in the cooling system.

This pump can cause in particular local pressure fluctuations in the fluid. The pressure fluctuations propagate in the form of coolant-borne sound (water-borne sound) throughout the cooling circuit, this type of dynamic disturbance being referred to as flow-induced vibration (FIV). In addition, flow-induced vibrations can also be caused for example by cross-sectional changes, deflections, valves in the cooling system or in other cooled components.

In addition to the disturbance caused by a flow of the fluid, the fluid can also transmit pressure fluctuations, which are referred to as transferred oscillations, even when the fluid is not flowing. These transferred oscillations can be caused by the flowing fluid itself (see above) or can have been transmitted to the fluid from the outside via cooling lines of the cooling system. The cooling lines are generally stiffly attached on support structures of the projection exposure apparatus, and therefore a mechanical oscillation of the support structure can be transmitted to the fluid and thus to a further component. The cooling line and the coolant itself can thus be regarded as a dynamic short circuit between support structures and components.

Each of the above-mentioned disturbances thus creates a local pressure fluctuation, which propagates in the form of a longitudinal fluid-borne soundwave through the fluid in the entire cooling system. When this soundwave reaches a temperature-controlled component, a term also used is received vibrations, i.e. that component of the disturbance that is created at another location and is passed on to the temperature-controlled component by fluid-borne sound. The pressure fluctuations cause dynamic reaction forces and moments in the temperature-controlled component, which can lead to a change in the position and/or alignment of the component in up to six degrees of freedom. Furthermore, the pressure fluctuations can cause high-frequency mechanical oscillations in all six degrees of freedom. Both disturbances can have an adverse effect on the imaging quality of the associated projection exposure apparatus.

Solutions known from the prior art are directed at decoupling the stiff attachments to the structures and/or at optimizing the line geometries. However, it has been shown that these measures are not always sufficient to meet the ever-increasing requirements for the positional stability of the components.

### SUMMARY

An object of the present invention is to specify a device that reduces or eliminates the above-described disadvantages of the prior art. Another object is to provide a method for reducing the effects of pressure waves on the imaging quality of a projection exposure apparatus.

These objects are achieved by a method and a projection exposure apparatus having the features of the independent claims. The dependent claims relate to advantageous developments and variants of the invention.

A method according to the invention for reducing the effect that parasitic forces and/or moments acting on a module of a projection exposure apparatus and caused by flow-induced pressure fluctuations or pressure fluctuations transferred via a fluid have on the imaging quality of the projection exposure apparatus comprises the following method steps:
determining the parasitic forces and/or moments,
defining at least two at least partially compensating forces and/or moments,
configuring the module to generate the compensating forces and/or moments.

In particular, the module can be configured as an optical module or a module for holding and positioning the wafer.

According to the invention, the configuration of the module thus allows the parasitic forces and/or moments caused during operation to be provided such that they have only a small influence, if any, on the imaging quality.

Furthermore, the configuration can be realized by the arrangement of and/or alignment of and/or the material selection for components of the module, in particular at least one supply line and one fluid channel of the module. As a result, the course of the fluid channels, which run for example in a module configured as a mirror module, and also the bends, cross sections and other variable parameters of the supply lines and fluid channels can be configured such that the parasitic forces and/or moments caused is reduced, on the one hand, and/or the sum of their effect is influenced such that the remaining resultant forces and/or moments have a minimal influence on the imaging quality, on the other hand. The forces and/or moments can be provided for example such that two or more forces and/or moments compensate for one another, and therefore the resultant parasitic forces and/or moments are reduced.

In particular, the resultant parasitic forces and/or moments can be reduced for at least a partial region of the module of the projection exposure apparatus. In other words, it is possible for example for only the supply lines to be configured so that no parasitic forces and/or moments act on the module, but the fluid lines within the mirror of a mirror module are optimized not with regard to the reduction of the parasitic forces and/or moments, but rather for example for a uniform temperature of the optical effective surface.

In a further embodiment, the resultant parasitic forces and/or moments can be reduced for a module. In this case, the component of the effect of this module, considered individually, can be reduced within the scope of the design freedoms, i.e. without considering the imaging quality of the projection exposure apparatus as a whole.

In particular, a shift and/or rotation of the optical module caused by the resultant parasitic forces and/or moments can be reduced. The shifts and/or rotations can be sized such that the contribution to the imaging quality of the optical module and thus to the imaging quality of the projection exposure apparatus is reduced. A shift of a rigid body of an optical element, configured as a mirror, of the optical module in the direction of the used light can be corrected for example relatively easily by moving another optical element, whereas a shift of the mirror parallel to an optical effective surface formed on the mirror requires further corrective measures.

Furthermore, an optical effect of the optical module can be determined by multiplying the shift and/or rotation of the optical module by corresponding optical sensitivities. This has the advantage that the effects of disturbances on the imaging quality of the projection exposure apparatus can be acquired directly.

This advantageously allows the resultant parasitic forces and/or moments to be provided so that the parasitic optical effect of the optical module is reduced. This can mean for example that, on account of different degrees of optical sensitivity for different degrees of freedom of a mirror, a weighting of the resultant shifts and/or rotations at module level leads to a smaller parasitic optical effect than a reduction of same based exclusively on the magnitude of the parasitic forces and/or moments.

In the case of a high optical sensitivity to a shift of the optical element parallel to the optical effective surface and a low optical sensitivity to a rotation of the optical element about an optical axis formed on the vertex of the optical effective surface and perpendicular to the optical effective surface, the module can thus be configured for example so that the parasitic forces and/or moments cause a relatively small shift, if any, parallel to the optical effective surface at the expense of a relatively large rotation about the optical axis.

In a further embodiment of the method, the resultant parasitic optical effects of the optical modules can be added to a resultant parasitic optical effect of a projection optics unit of the projection exposure apparatus, as a result of which an overall effect relevant to the imaging is determined.

In particular, the resultant parasitic forces and/or moments can be provided so that the resultant parasitic optical effect of the projection optics unit is reduced, as a result of which the effect of the resultant parasitic optical effect of all the optical modules can be minimized. This advantageously minimizes the contribution of the projection optics unit of the projection exposure apparatus.

A projection exposure apparatus according to the invention comprises at least one module, wherein the module comprises a fluid channel, which at least temporarily contains a pressurized fluid. The fluid channel is further connected to supply lines, which are connected to a support frame via bearing points. The projection exposure apparatus is distinguished in that the module is symmetrical.

Symmetrical within the meaning of the invention includes for example not only a purely geometric symmetry but also a design-related symmetry, i.e. also an active symmetry or effective symmetry, which is distinguished by a reduction of the parasitic effect, such as parasitic optical effects of an optical module. For example the causes of the parasitic effects, such as the parasitic forces and/or moments, can be implemented by compensating for the cause or by one cause cancelling another out. The effective symmetry can refer to forces and/or moments, shifts and/or rotations and to optical effects of multiple modules configured as optical modules.

In a further embodiment, the supply lines can be located in a plane. This has the advantage that parasitic forces arising in the plane, in particular the resultant parasitic forces caused by overlaying all the parasitic forces, on account of the arrangement in a plane do not cause any moments as a result of the lack of a lever arm. This advantageously avoids tilting of the module about the two mutually perpendicular axes of the plane.

In particular, the plane can be perpendicular to an axis that has a minimal optical effect on the imaging when the module rotates about this axis. In the case of a plane optical effective surface, the axis would be for example perpendicular thereto. On account of the usually rotationally symmetrical optical elements, a rotation about this axis can cause no or only a negligibly small parasitic optical effect. A tilt or rotation about this axis that can be caused by the parasitic forces caused in the plane thus still has no effect on the imaging quality of the projection exposure apparatus.

In a further embodiment of the invention, the supply lines can run in the plane at least as far as the bearing points. Parasitic forces which are a portion of the resultant parasitic forces acting on the module also act at the bearing points due to the attachment to the support frame. Forces in the supply lines caused beyond the bearing points are supported by the bearing points and thus do not act on the module, as a result of which the flow layout of the supply lines beyond the bearing points can be continued as desired, so they no longer have to run in the plane. This has the advantage of being able to adapt the supply lines in the frequently limited available installation space.

In a further embodiment of the invention, at least one decoupling element arranged in the supply lines can be located within the plane. This decoupling element is used to decouple the parasitic forces and moments introduced from the support frame via the bearing points and/or caused in the supply lines.

Furthermore, at least two mutually perpendicular decoupling elements can be located above the attachment of the supply line to the bearing point, wherein for example the decoupling elements can advantageously be stiff in the axial direction and flexible in the lateral direction.

In this context, stiff is intended to mean that the stiffness of the decoupling elements is as high as possible in the context of the design and the technical properties of the material used, such as yield strengths or flexural strengths, and/or component part geometries, such as wall thicknesses. By contrast, flexible is understood to mean a lowest possible stiffness in the context of the design and the technical properties of the material used and/or the component part geometry.

The decoupling elements are configured for example as corrugated hoses, the axial and lateral stiffness of which can be set on the basis of the wall thickness, the radii of and the distance between the individual corrugations, and the length of the corrugated hose.

In particular, the component can be decoupled from the bearing points in all six degrees of freedom. This can be achieved, for example, by the above-described arrangement at a 90° angle, other arrangements and/or decoupling elements also being able to allow decoupling in all six degrees of freedom.

In a further embodiment of the invention, the fluid channels and/or the supply lines can be configured such that the resultant parasitic forces and/or moments that are generated by the pressurized fluid are reduced within a module. In this case, the symmetrical design of the module does not necessarily relate to the geometric arrangement, but rather to the symmetry of the resultant parasitic forces and moments, as a result of which they at least partially compensate for one another. The greater the degree of symmetry of the forces, the lower the resultant parasitic forces and/or moments are.

In a further embodiment of the invention, the fluid channels and/or the supply lines can be configured so that a shift and/or rotation of the optical module caused by the resultant parasitic forces and/or moments is reduced. In this case, in turn, the symmetry relates to an effective symmetry of the resultant parasitic forces and/or moments, which advantageously minimizes the shifts and/or rotations (tilts) caused by the resultant parasitic forces and/or moments.

As a result of the scanning movement performed in projection exposure apparatuses when the structure of a reticle is being imaged onto a wafer in the y-direction, a shift in the scanning direction, i.e. in the y-direction, has less effect on the imaging of the structure on the wafer than a shift in the x-direction, which is perpendicular to the scanning direction. This is based on the fact that a shift in scanning direction is averaged out by the scanning process, a shift perpendicular to the scanning direction causing the image to shift. The design of the module can thus take in particular this aspect into account, so that the resultant force acts in the direction of the y-direction, this in turn corresponding to an effective symmetry.

In particular, the fluid channels and/or the supply lines can be configure such that the resultant parasitic forces and/or moments are provided so that the resultant parasitic optical effect of the optical module is reduced. As above, the symmetry relates to an effective symmetry of the shifts and/or rotations, multiplied by optical sensitivities, on account of the resultant parasitic forces and/or moments. The higher the degree of symmetry of the individual optical effects, the lower the remaining parasitic optical effect of the module is. Symmetry relates for example to oppositely acting optical effects, and the optical effects of a shift and a rotation of the module are thus mirror-symmetrical in relation to one another, as a result of which at least the symmetrical components compensate for one another. It is possible for example on the basis of the optical sensitivities for shifts and/or tilts in degrees of freedom with a low optical sensitivity, such as the above-explained rotation about the axis aligned perpendicularly to the plane, to become relatively large for the benefit of a shift and/or rotation in a direction with high optical sensitivities.

In a further embodiment, the fluid channels and/or the supply lines can be configured such that the resultant parasitic forces and/or moments are provided so that the resultant parasitic optical effect of the projection optics unit is reduced. In this case, the symmetrical design of the module relates to the effective symmetry of the individual modules in relation to one another. As in the case of the intramodular symmetry explained above, this relates to an intermodular symmetry of the optical effects. The optical effect of a module can be mirror-symmetrical in relation to an optical effect of a second module from the point of view of the projection optics unit, and therefore at least the symmetrical components of the optical effects of the modules compensate for one another.

Furthermore, the module can be configured as an optical module and/or a module for holding and positioning a wafer.

Alternatively, the module can also be configured as another component of the projection exposure apparatus, in particular a reference structure. The reference structure can serve in particular as a reference for the positioning of the optical modules and/or other components of the projection exposure apparatus. As a result, the requirements for the positional stability and dimensional stability of the reference structure are relatively high, since any movement of a reference element and/or sensor arranged on the reference structure leads to a parasitic movement of the corresponding mirror module or of another component. In particular, the module can have a symmetrical structure with respect to a reference point provided on the module. The reference point can for example be the origin of an optical coordinate system to which the optical sensitivities relate. The optical coordinate system can be used to adjust the optical element in the optical module and, in the case of a positionable module, to control the position of the optical module. This has the advantage that the reduction acts independently of the position of the optical module, i.e. brings about a constant reduction of the effects.

### BRIEF DESCRIPTION OF THE DRAWINGS

Exemplary embodiments and variants of the invention are explained in more detail below with reference to the drawing, in which:

FIG. 1 schematically shows a meridional section of a projection exposure apparatus for EUV projection lithography,

FIG. 2 schematically shows a meridional section of a projection exposure apparatus for DUV projection lithography,

FIG. 3 shows a schematic illustration of a mirror module known from the prior art,

FIG. 4 shows a further schematic illustration of a mirror module known from the prior art, and

FIG. 5 shows a schematic illustration of a mirror module according to the invention, and

FIG. 6 shows a schematic illustration of a further mirror module according to the invention.

### DETAILED DESCRIPTION

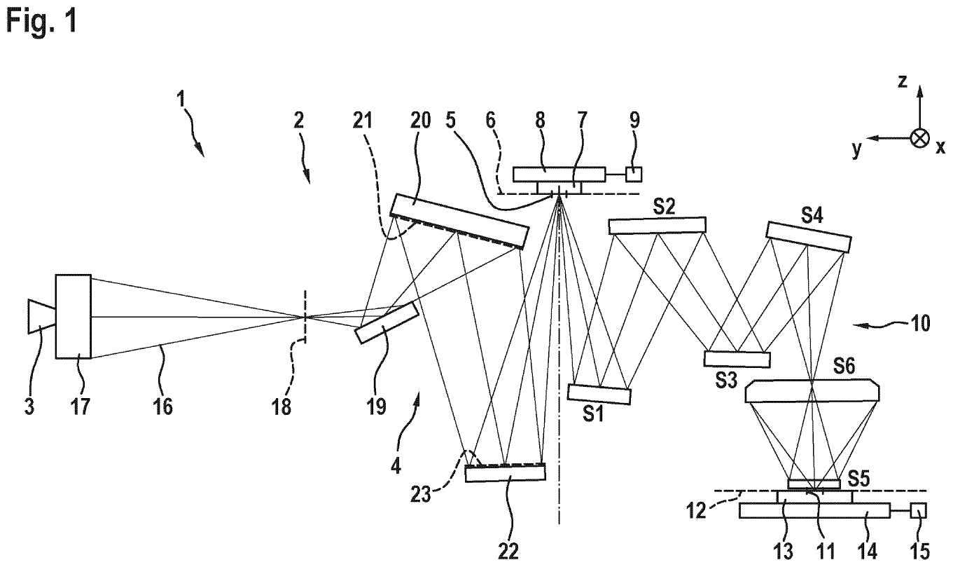

In the following text, the salient constituent parts of a microlithographic projection exposure apparatus 1 are described by way of example initially with reference to FIG. 1. The description of the fundamental setup of the projection exposure apparatus 1 and the constituent parts thereof are understood here to be non-limiting.

One embodiment of an illumination system 2 of the projection exposure apparatus 1 has, in addition to a radiation source 3, an illumination optics unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable in particular in a scanning direction with a reticle displacement drive 9.

A Cartesian xyz-coordinate system is depicted in FIG. 1 for explanation purposes. The x-direction runs perpendicularly into the plane of the drawing. The y-direction runs horizontally, and the z-direction runs vertically. The scanning direction runs in the y-direction in FIG. 1. The z-direction runs perpendicularly in relation to the object plane 6.

The projection exposure apparatus 1 comprises a projection optics unit 10. The projection optics unit 10 is used to image the object field 5 into an image field 11 in an image plane 12. The image plane 12 runs parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable, in particular in y direction, with a wafer displacement drive 15. The displacement on the one hand of the reticle 7 with the reticle displacement drive 9 and on the other hand of the wafer 13 with the wafer displacement drive 15 can take place so as to be synchronized with one another.

The radiation source 3 is an EUV radiation source. The radiation source 3 emits in particular EUV radiation 16, which is also referred to below as used radiation, illumination radiation or illumination light. The used radiation has in particular a wavelength in the range of between 5 nm and 30 nm. The radiation source 3 can be a plasma source, for example a laser-produced plasma (LPP) source or a gas discharge-produced plasma (GDPP) source. It can also be a synchrotron-based radiation source. The radiation source 3 may be a free electron laser (FEL).

The illumination radiation 16 emanating from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 may represent a separation between a radiation source module, comprising the radiation source 3 and the collector 17, and the illumination optics unit 4.

The illumination optics unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the pure deflection effect. As an alternative or in addition, the deflection mirror 19 may take the form of a spectral filter that separates a used light wavelength of the illumination radiation 16 from extraneous light of a wavelength differing therefrom. If the first facet mirror 20 is arranged in a plane of the illumination optics unit 4 that is optically conjugate to the object plane 6 as a field plane, it is also referred to as a field facet mirror. The first facet mirror 20 comprises a multiplicity of individual first facets 21, which are also referred to below as field facets. FIG. 1 illustrates only some of these facets 21 by way of example.

The first facets 21 may take the form of macroscopic facets, in particular rectangular facets or facets with an arcuate edge contour or an edge contour of part of a circle. The first facets 21 can be in the form of plane facets or alternatively in the form of convexly or concavely curved facets.

As is known for example from DE 10 2008 009 600 A1, the first facets 21 themselves may also be composed in each case of a multiplicity of individual mirrors, in particular a multiplicity of micromirrors. The first facet mirror 20 may in particular be in the form of a microelectromechanical system (MEMS system). For details, reference is made to DE 10 2008 009 600 A1.

The illumination radiation 16 travels horizontally, i.e. in the y-direction, between the collector 17 and the deflection mirror 19.

In the beam path of the illumination optics unit 4, a second facet mirror 22 is disposed downstream of the first facet mirror 20. If the second facet mirror 22 is arranged in a pupil plane of the illumination optics unit 4, it is also referred to as a pupil facet mirror. The second facet mirror 22 may also be arranged at a distance from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which can for example have a round, rectangular or else hexagonal boundary, or may alternatively be facets composed of micromirrors. In this regard, reference is likewise made to DE 10 2008 009 600 A1.

The second facets 23 can have plane or alternatively convexly or concavely curved reflection surfaces.

The illumination optics unit 4 thus forms a doubly faceted system. This basic principle is also referred to as a fly's eye integrator.

It can be advantageous to arrange the second facet mirror 22 not exactly in a plane that is optically conjugate to a pupil plane of the projection optics unit 10. In particular, the pupil facet mirror 22 may be arranged with a tilt relative to a pupil plane of the projection optical unit 10, as described for example in DE 10 2017 220 586 A1.

The second facet mirror 22 is used to image the individual first facets 21 into the object field 5. The second facet mirror 22 is the last beam-shaping mirror or actually the last mirror for the illumination radiation 16 in the beam path upstream of the object field 5.

In a further embodiment (not illustrated) of the illumination optics unit 4, a transfer optics unit contributing in particular to the imaging of the first facets 21 into the object field 5 may be arranged in the beam path between the second facet mirror 22 and the object field 5. The transfer optics unit may have exactly one mirror, or alternatively two or more mirrors arranged one behind another in the beam path of the illumination optics unit 4. The transfer optics unit may in particular comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the field facet mirror 20 and the pupil facet mirror 22.

In another embodiment of the illumination optics unit 4, the deflection mirror 19 may also be omitted, and so the illumination optics unit 4 can then have exactly two mirrors downstream of the collector 17, specifically the first facet mirror 20 and the second facet mirror 22.

The imaging of the first facets 21 into the object plane 6 through the second facets 23 or using the second facets 23 and a transfer optics unit is generally only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors S1 to S6. Alternatives with four, eight, ten, twelve or any other number of mirrors Si are likewise possible. The penultimate mirror S5 and the last mirror M6 each have a through opening for the illumination radiation 16. The projection optics unit 10 is a doubly obscured optics unit. The projection optics unit 10 has an image-side numerical aperture that is greater than 0.5 and can also be greater than 0.6 and for example can be 0.7 or 0.75.

Reflection surfaces of the mirrors Si may be in the form of free-form surfaces without an axis of rotational symmetry. Alternatively, the reflection surfaces of the mirrors Si may be configured as aspherical surfaces with exactly one axis of rotational symmetry of the reflection surface shape. Just like the mirrors of the illumination optics unit 4, the mirrors Si may have highly reflective coatings for the illumination radiation 16. These coatings may be in the form of multilayer coatings, in particular with alternating layers of molybdenum and silicon.

The projection optics unit 10 has a large object-image shift in the y-direction between a y-coordinate of a center of the object field 5 and a y-coordinate of the center of the image field 11. This object-image shift in the y-direction can be of approximately the same magnitude as a z-distance between the object plane 6 and the image plane 12.

In particular, the projection optics unit 10 may have an anamorphic design. In particular, it has different imaging scales βx, βy in the x- and y-directions. The two imaging scales βx, βy of the projection optics unit 10 are preferably (βx, βy)=(+/−0.25, +/−0.125). A positive imaging scale β means imaging without image inversion. A negative sign for the imaging scale β means imaging with image inversion.

The projection optics unit 10 thus leads to a reduction in size with a ratio of 4:1 in the x-direction, i.e. in a direction perpendicular to the scanning direction.

The projection optics unit 10 leads to a reduction in size with a ratio of 8:1 in the y-direction, i.e. in the scanning direction.

Other imaging scales are likewise possible. Imaging scales with the same signs and the same absolute values in the x- and y-directions, for example with absolute values of 0.125 or 0.25, are also possible.

The number of intermediate image planes in the x-direction and in the y-direction in the beam path between the object field 5 and the image field 11 can be the same or can be different, depending on the embodiment of the projection optics unit 10. Examples of projection optics units with different numbers of such intermediate images in the x- and y-directions are known from US 2018/0074303 A1.

In each case one of the pupil facets 23 is assigned to exactly one of the field facets 21 for the purpose of forming a respective illumination channel for illuminating the object field 5. In particular, this may result in illumination according to the Köhler principle. The far field is decomposed into a plurality of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is in particular as homogeneous as possible. It preferably has a uniformity error of less than 2%. Field uniformity can be achieved by overlaying different illumination channels.

The illumination of the entrance pupil of the projection optics unit 10 can be defined geometrically with an arrangement of the pupil facets. The intensity distribution in the entrance pupil of the projection optics unit 10 may be set by selecting the illumination channels, in particular the subset of the pupil facets that guide light. This intensity distribution is also referred to as illumination setting.

A likewise preferred pupil uniformity in the region of portions of an illumination pupil of the illumination optics unit 4 that are illuminated in a defined manner may be achieved by a redistribution of the illumination channels.

Further aspects and details of the illumination of the object field 5 and in particular of the entrance pupil of the projection optics unit 10 are described below.

The projection optics unit 10 may have in particular a homocentric entrance pupil. The latter may be accessible. It may also be inaccessible.

The entrance pupil of the projection optics unit 10 cannot, as a rule, be exactly illuminated using the pupil facet mirror 22. The aperture rays often do not intersect at a single point in the event of imaging by the projection optics unit 10 that telecentrically images the center of the pupil facet mirror 22 onto the wafer 13. However, it is possible to find an area in which the spacing of the aperture rays, which is determined in pairs, becomes minimal. This area is the entrance pupil or an area conjugate thereto in real space. In particular, this area exhibits a finite curvature.

It may be the case that the projection optics unit 10 has different poses of the entrance pupil for the tangential beam path and for the sagittal beam path. In this case, an imaging element, in particular an optical component of the transfer optics unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

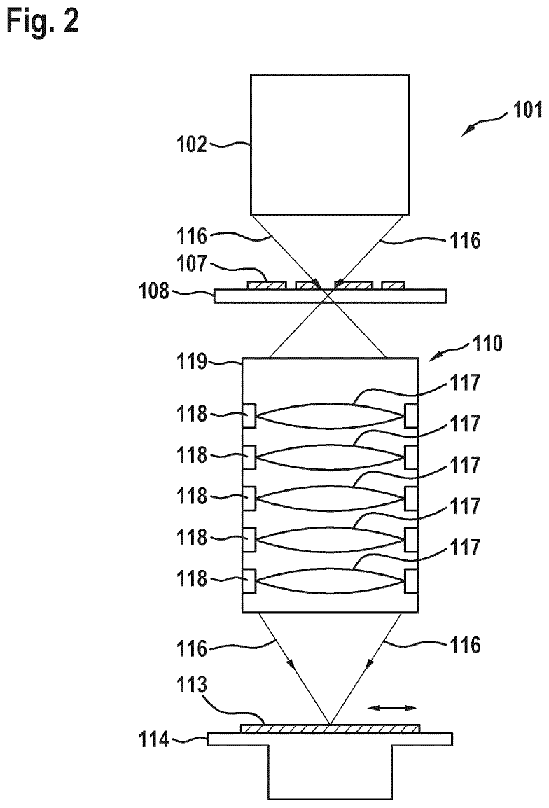

FIG. 2 schematically shows a meridional section through a further projection exposure apparatus 101 for DUV projection lithography, in which the invention can likewise be used.

The setup of the projection exposure apparatus 101 and the principle of the imaging are comparable with the setup and procedure described in FIG. 1. Identical components are denoted by a reference sign increased by 100 relative to FIG. 1, i.e. the reference signs in FIG. 2 start at 101.

By contrast to an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the greater wavelength of the DUV radiation 116, employed as used light, in the range of 100 nm to 300 nm, in particular in the region of 193 nm. The projection exposure apparatus 101 in this case comprises an illumination system 102, a reticle holder 108 for receiving and exactly positioning a reticle 107, which is provided with a structure and is used to determine the later structures on a wafer 113, a wafer holder 114 for holding, moving, and exactly positioning this very wafer 113, and a projection lens 110, with a plurality of optical elements 117 held by mounts 118 in a lens housing 119 of the projection lens 110.

The illumination system 102 provides DUV radiation 116 required for the imaging of the reticle 107 on the wafer 113. A laser, a plasma source or the like can be used as the source of this radiation 116. The radiation 116 is shaped in the illumination system 102 with optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the setup of the downstream projection optics unit 101 with the lens housing 119 does not differ in principle from the setup described in FIG. 1 and is therefore not described in further detail.

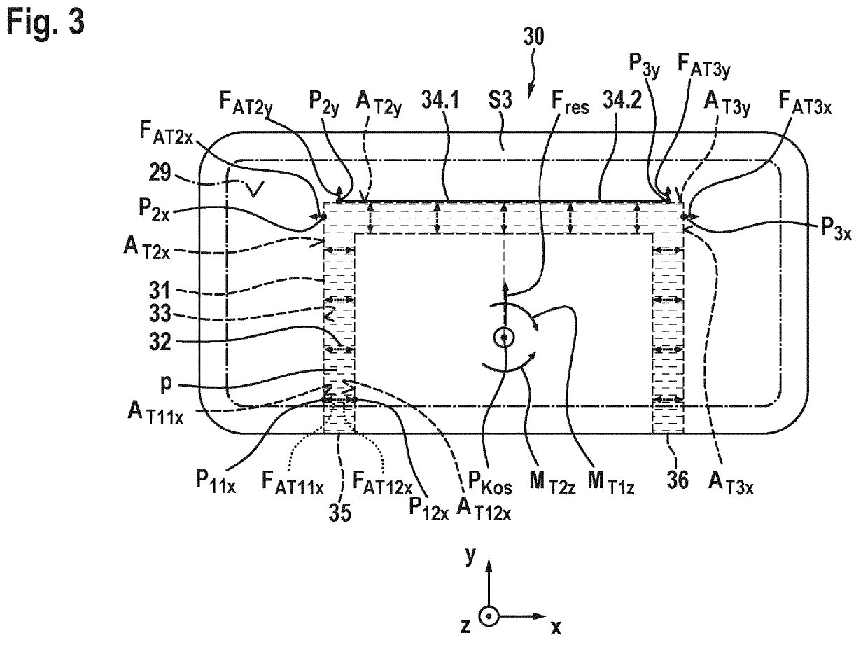

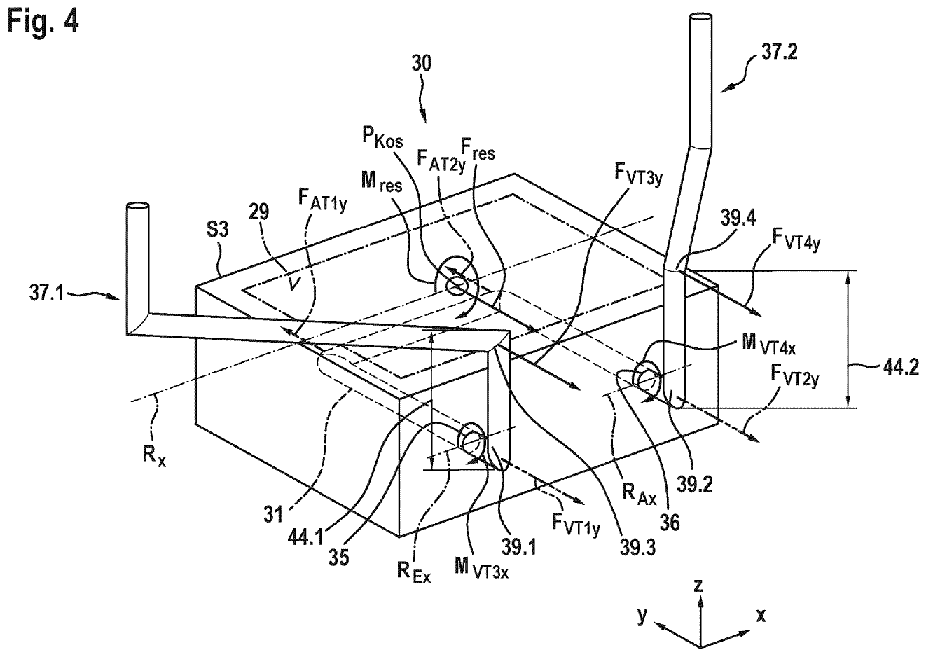

FIG. 3 shows a plan view of a schematic illustration of a mirror module 30 known from the prior art with an optical element which in the embodiment shown is configured as a mirror S3, as can be used in the projection exposure apparatus 1 explained in FIG. 1. The mirror S3 has a fluid channel 31, which is shown in dashed lines in FIG. 3 and through which a fluid in the form of water 32 flows. The fluid channel 31 comprises an inlet 35 and an outlet 36, which can be connected to a water preparation and provision device via a supply line 37.1, 37.2 (FIG. 4).

In the example illustrated, a constant pressure p is applied to the water 32 in the fluid channel 31 and the mirror S3 is assumed to have infinite stiffness. The pressure p acts simultaneously in all spatial directions, and therefore a force FATv acts on the fluid channel 31 and thus on the mirror S3 for each partial area ATv of the inner surface 33 of the fluid channel 31.

The index “v” comprises in the first instance a sequential number of the surfaces or forces and in the second instance the effective direction of the force or alignment of the surface in the Cartesian coordinate system illustrated in FIG. 3. Opposing surfaces/forces comprise a two-digit number, with the first sequential digit denoting the location of the surface/force and a second number which makes a distinction between the surfaces/forces, as in the case of the opposing forces F_{AT11x}, F_{AT12x} illustrated in the example. The forces F_{ATv} acting on the partial areas A_{Tv} result from the pressure p, the partial area A_{Tv} and the normal vector n, with the normal vector \vec{n} being omitted in the Figures and in the formulae for the sake of clarity, whereby in absolute terms a force F_{ATv} yields

$${F}_{ATv} = p * {A}_{Tv} .$$

For the sake of clarity, to describe the mode of operation of the forces FATv, FIG. 3 uses reference signs to denote by way of example only two opposing areas AT11x, AT12x and the two forces FAT11x, FAT12x corresponding to the areas AT11x, AT12x in the x-direction.

The forces FATv each act at a force action point Py, which follows the same nomenclature as the surfaces/forces and lies in the surface centroid of the areas ATv. In the case of areas AT11x, AT12x of the same size, the two forces FAT11x, FAT12x also have the same magnitude and act in opposite directions, and therefore the forces FAT11x, FAT12x cancel one another out and do not cause any resultant force on the mirror S3.

The further pairs of forces FATv, FATv, which lie perpendicularly to the pipe and cancel one another out, are illustrated in FIG. 3 as dotted arrows only for the plane of the drawing, which is designated as the x-y plane, and, as explained above, are not provided with reference signs. Exceptions are the forces F_{AT2x}, F_{AT2y}, F_{AT3X}, F_{AT3y} with the force action points P₂ₓ, P_{2y}, P₃ₓ, P_{3y}, which lie in the deflections of the fluid channel 31. They have no directly opposite surfaces and therefore no compensating force, either. The forces F_{AT2x} and F_{AT3x} also cancel one another out in the case of a constant pressure p across the great distance between the force action points P₂ₓ, P₃ₓ, so that no resultant force acts on the mirror S3 in the x-direction.

In the example of FIG. 3, the mirror S3 is open at the inlet 35 and outlet 36, i.e. within the mirror S3 there is no area ATv on which the pressure can cause a force FATv. As a result, the forces FAT2y, FAT3y opposite the inlet 35 and the outlet 36 cannot be compensated for in the mirror S3.

As a result, a resultant force Fres corresponding to the sum of the two forces FAT2y, FAT3y and acting in the y-direction in FIG. 3 acts on the mirror S3. The force Fᵣₑₛ acts on a reference point P_{Kos} of the mirror S3 and causes the mirror S3 to shift from its intended position.

In the example shown, the reference point PKos corresponds to the origin of the mirror coordinate system, this origin being used both for the adjustment of the optical mirrors Si (FIG. 1) relative to one another and as the basis for the positioning of the mirror S3 relative to a reference.

The resultant force Fres thus acts on the mirror S3 depending on the pressure p, which varies over time owing to the above-explained pressure fluctuations in the water 32. The resultant shift of the mirror S3 from its intended position, or the vibration about an intended position, is thus not constant, but changes over time as the pressure p changes. This has an adverse effect on the imaging quality of the projection exposure apparatus 1, as explained above.

The moments MAT3z, MAT4z acting on the mirror S3 between the points of action P2y, P3y of the forces FAT2y, FAT3y and the reference point PKos owing to the forces FAT2y, FAT3y and the lever arms 34.1, 34.2 cancel one another out by virtue of the symmetry of the mirror module 30.

On account of the infinite stiffness of the mirror S3, the forces F_{ATv} brought about by the pressure p in the fluid channel 31 do not cause any deformation of the mirror S3 or of an optical effective surface 29 located on the mirror S3 and used for imaging the structures onto the wafer 13 (FIG. 1).

FIG. 4 shows a schematic illustration of the mirror module 30 known from the prior art, as explained in FIG. 3. In the example shown, in addition to the embodiment in FIG. 3, the mirror module 30 comprises a feed line 37.1 and a discharge line 37.2 for supplying the fluid channel 31 with water 32, these lines being referred to below as supply lines 37.1, 37.2. The supply lines 37.1, 37.2 are connected at one end to the inlet 35 or outlet 36, respectively, of the fluid channel 31 and at the other end are open in a manner comparable to the mirror S3 in FIG. 3 for illustrating the effect of the forces FATv acting on the fluid channel 31, and therefore no forces can be caused at this end owing to the missing area ATv.

The supply lines 37.1, 37.2 are configured so that the resultant forces FAT2y, FAT3y in FIG. 3 are compensated for by a force FV_{VT1y}, FV_{VT2y} caused at a deflection of the supply lines 37.1, 37.2 which is in the form of a 90° elbow piece 39.1, 39.2. The index “V” stands for a force generated in the supply line 37.1, 37.2 and serves to distinguish the forces FATY generated in the mirror S3. Further 90° elbow pieces 39.3, 39.4 at which, as described, the forces F_{VT3y}, F_{VT4y} are caused are provided in the further course of the supply lines 37.1, 37.2 running downstream of the elbow pieces 39.1, 39.2 in the z-direction. The further course of the supply lines 37.1, 37.2 runs at a 45° angle to the x-axis, although FIG. 4 only illustrates the force components F_{VT3y}, F_{VT4y} which act in the y-direction.

These forces FVT3y, FVT4y cause, via the lever arms 44.1, 44.2 formed in the z-direction, a moment MVT3x, MVT4x about the axis of rotation REx at the inlet 35 and about the axis of rotation RAx at the outlet 36, these moments acting on the mirror S3. The resultant force Fres that acts on the mirror S3 and the moment Mres, which like in FIG. 3 act at the reference point PKos of the mirror coordinate system or on an axis of rotation Rx running through the reference point PKos, respectively, cause a translational and/or rotational movement of the mirror S3. This brings about a deviation of the mirror S3 from its intended position, as a result of which the imaging quality of the projection exposure apparatus 1 is adversely affected.

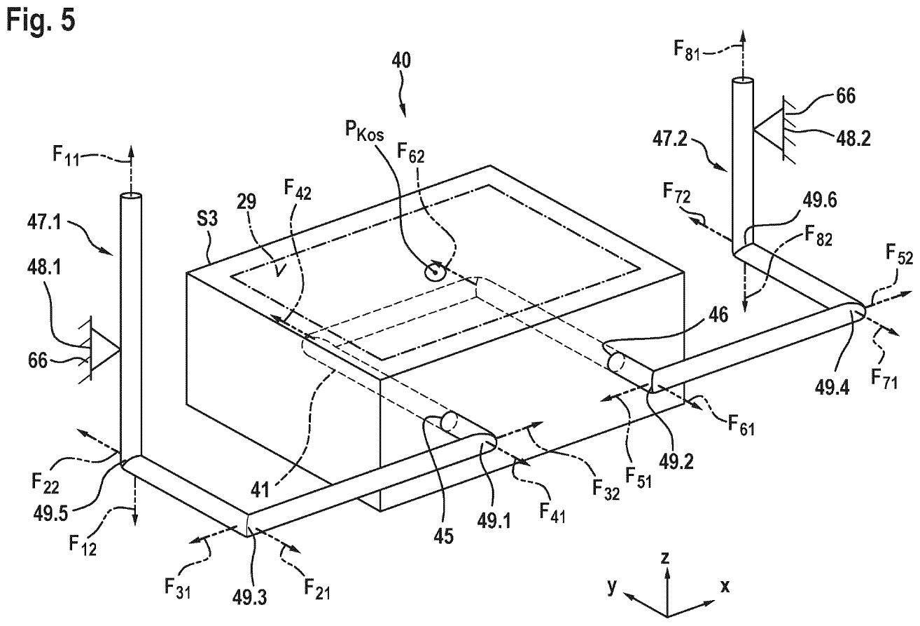

FIG. 5 shows a schematic illustration of a mirror module 40 according to the invention with a mirror S3 and supply lines 47.1, 47.2; where appropriate, corresponding elements are denoted by reference signs increased by 10 relative to the designation in FIG. 4. The supply lines 47.1, 47.2 are configured so that the deflections, which are also in the form of 90° elbow pieces 49.1, 49.2, 49.3, 49.4, 49.5, 49.6, of the supply lines 47.1, 47.2 lie in a plane with the fluid channel 31, the plane being provided parallel to the x-y plane of the mirror coordinate system. The supply lines 47.1, 47.2 are configured so that all of the forces Fuw caused at the elbow pieces 49.1, 49.2, 49.3, 49.4, 49.5, 49.6 in the x-y plane cancel one another out.

Using the nomenclature of the forces Fuw, the index “u” denotes a sequential number for a respective pair of forces, such as the pair of forces F11, F12, and the index “w” denotes the two forces F11, F12 respectively belonging to the pair of forces “u”. The arrangement of the supply lines 47.1, 47.2 in the plane of the fluid channel 41 also has the advantage that, in the case of parasitic resultant forces within the plane on account of the missing lever arm, no moments about the x-axis or the y-axis can be introduced into the mirror S3.

The supply lines 47.1, 47.2 are fixedly connected to a support frame 66 of the projection exposure apparatus 1 (FIG. 1) via bearing points 48.1, 48.2. The forces F12, F82 are therefore compensated for by bearing forces F11, F81 acting on the bearing points 48.1, 48.2. Therefore, assuming a constant pressure p in the fluid channel 41 and in the supply lines 47.1, 47.2 and a mirror S3 of infinite stiffness and supply lines 47.1, 47.2 of infinite stiffness, no resultant forces Fres owing to non-compensated forces Fuw act on the mirror S3. This clearly represents an idealized state and serves to explain the mode of operation of the invention with regard to the reduction of the effects of the forces Fuw on the imaging quality of the projection exposure apparatus 1 (FIG. 1) by a symmetrical arrangement of the fluid channel 41, of the supply lines 47.1, 47.2 and of the bearing points 48.1, 48.2. The invention comprises in particular the configuration of the components of the mirror module 40, such as the fluid channel 41, the supply lines 47.1, 47.2 and the bearing points 48.1, 48.2, and also further components that can be set up to reduce the effects of the forces Fuw on the imaging quality of the projection exposure apparatus 1.

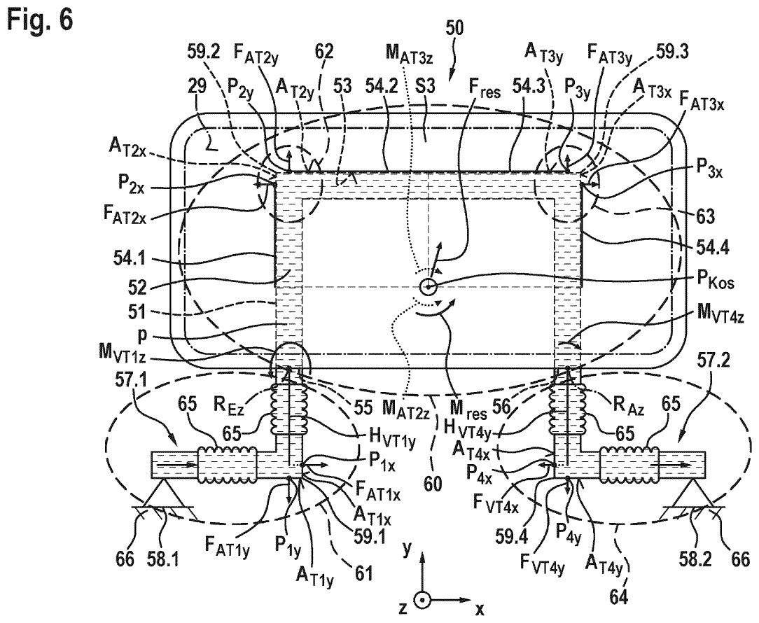

FIG. 6 shows a plan view of a schematic illustration of a mirror module 50 according to the invention with a mirror S3 and supply lines 57.1, 57.2, as explained in FIG. 5; where appropriate, corresponding elements are denoted by reference signs increased by 10 relative to the designation in FIG. 5.

By contrast to the idealized conditions in FIG. 5, in FIG. 6 the pressure p in the supply lines 57.1, 57.2 and in the fluid channel 51 decreases in the flow direction (indicated in FIG. 6 by an arrow). The pressure p is thus greater at the start of the supply line 57.1 than at the end of the supply line 57.2, as a result of which the forces F_{ATv} acting on the deflections 59.1, 59.2, 59.3, 59.4 are no longer equal in magnitude. By contrast to the idealized representation of the mirror module 40 in FIG. 5, the supply lines 57.1, 57.2 of the mirror module 50 run in the plane (x-y plane) of the fluid channel 51 as far as the attachment to the bearing points 58.1, 58.2, as a result of which a tilting of the mirror S3 about the x-axis or y-axis on account of the parasitic force caused by the pressure difference between the inlet and outlet is avoided.

The supply lines 57.1, 57.2 additionally comprise bellows 65, which serve to decouple the mirror S3 from the support frame 66 rigidly attached via the bearing points 58.1, 58.2 and are also located in the x-y plane. By contrast to the example in FIG. 5, the supply lines 57.1, 57.2, in particular the bellows 65, are not ideally stiff and deform owing to the pressure p, as a result of which the magnitude and direction of the forces FVTef acting on the supply lines 57.1, 57.2 are influenced, and the forces FVTef therefore depend, among other things, on the stiffness of the bellows 65. The index “e” of the nomenclature stands for a sequential number of a region 61, 62, 63, 64, at which various forces, such as FVT1x, FVT1y, act on force action points P1x, P1y and cause moments, such as MVT1z, about an axis of rotation REz at the inlet 55 of the fluid channel 51. The index “f” of the nomenclature stands for the direction of the force FVT1x, FVT1y or the axis of rotation REz of the moment MVT1z caused. The nomenclature also applies equivalently to the force action points Pef. The bellows 65 are located above the attachment to the bearing points 58.1, 58.2, and this ensures a decoupling of the mirror S3 from the support frame 66. The bellows 65 are perpendicular to one another and are stiff in the axial direction and flexible in the lateral direction, and this ensures a decoupling of the mirror S3 in all six degrees of freedom.

The forces FVTef, which become increasingly smaller in the different regions 61, 62, 63, 64 owing to the decreasing pressure p on the supply lines 57.1, 57.2 and the mirror S3, thus cause moments MVTef of different magnitudes, as a result of which both a resultant force Fres and a resultant moment Mres are caused on the mirror S3 at the point PKos and about the axis of rotation running through the point PKos in the z-direction, respectively.

Using the example of the force FVT1x in the x-direction at the force action point P1x, the effects will be explained hereinafter. The force FVT1x, via the lever arm HVT1y, causes a moment MVT1z about an axis of rotation REz at the inlet 55 of the mirror S3. On account of the pressure difference between the force action point P1x of FVT1x and the force action point P4x of FAT4x, this moment MVT1z is greater than the corresponding moment MAT4z caused by the force FAT3x about an axis of rotation RAz at the outlet 56 of the mirror S3 in the region 64. In the case of a constant pressure p, the moments MVT1z, MVT4z would compensate for one another on account of the lever arms HVT1y, HVT4y of the same length (see idealized explanation in FIG. 5).

It should be noted that, in addition to the pressure drop through the supply lines 57.1, 57.2 and the fluid channel 51, even if the pressure p is constant a deformation of the supply lines 57.1, 57.2 can lead to forces FVTef which have different magnitudes and also cause a resultant moment Mres.

The further moments MAT2z, MAT3z, which are caused by the forces FAT2x, FAT2y, FAT3x, FAT3y of different magnitudes and the lever arms 54.1, 54.2, 54.3, 54.4, do not influence the direction of rotation of the resultant Mres, because in the case of lever arms 54.1, 54.2, 54.3, 54.4 of the same lengths, the moments MAT2z, MAT3z have equal and opposite magnitudes, thus compensating for one another.

Furthermore, the force (not depicted) formed from the difference between FVT1y and FAT2y and the force (not illustrated) formed from the difference between FAT3y and FVT4y cause a moment (not illustrated) with the same direction of rotation, as a result of which these moments are added to one another and contribute to the resultant moment Mres.

All of the forces FVT1x, FAT2x, FAT3x, FVT4x shown in FIG. 6 thus cause a resultant force Fres on the mirror S3 and the moments MVT1z, MAT2z, MAT3z, MVT4z caused by the forces FVT1x, FAT2x, FAT3x, FVT4x cause a resultant moment Mres, as a result of which the imaging quality of the projection exposure apparatus 1 (FIG. 1) is adversely affected.

In a first method for reducing the effects of flow-induced vibrations and vibrations transferred in the fluid 52 on the imaging quality of a projection exposure apparatus 1, 101, in a first step the mirror S3 is split into three regions 60, 61, 64 corresponding to the mirror S3, the feed line 57.1 and the discharge line 57.2.

In a second step, each of the regions 60, 61, 64 is optimized individually, i.e. the forces FVTef, FATef caused by the pressure p acting on the partial areas ATef and the resultant moments MVTef are minimized.

The reduction can be realized by adapting the geometry, arrangement and alignment of the supply lines 57.1, 57.2, of the bellows 65 and of the fluid channel 51, and also adapting the stiffness and other physical properties of the supply lines 57.1, 57.2 and of the bellows 65.

In a third step, the resultant force Fres, which was caused by the individual forces FVTef, FATef, and the resultant moment Mres are determined and minimized.

The third step can also lead to the forces FVTef and moments MVTef that were optimized in the first step being adapted toward larger values and directions which deviate from the local optimization. In the regions 60, 61, 64, the forces therefore cannot correspond to the local minimum FVTef, even though the resultant movement of the mirror S3 is minimized.

In this case, in particular in the case of the resultant force Fres, not only the magnitude of the force Fᵣₑₛ and/or moment Mᵣₑₛ but also the direction of the force Fᵣₑₛ and/or moment Mᵣₑₛ plays a crucial role. Owing to the scanning movement described in FIG. 1, which is performed in the y-direction in the case of the imaging of the structure of the reticle 7 onto the wafer 14, a shift affects the imaging of the structure on the wafer 14 less strongly in the scanning direction, i.e. in the y-direction, than in the x-direction, which is perpendicular to the scanning direction, since a shift in the scanning direction is averaged out by the scanning process, a shift perpendicular to the scanning direction causing the imaging to shift.

The method described on the basis of an optical module configured as the mirror M3 applies, mutatis mutandis, to a module for holding and positioning a wafer and can also be applied thereto.

In a further method for reducing the effects of flow-induced and transferred vibrations on the imaging quality of a projection exposure apparatus 1, 101, not only the optimization of the resultant force Fᵣₑₛ and the resultant moment Mᵣₑₛ based solely on the magnitude and the direction but also the optical sensitivities relevant for the imaging are taken into account. In this case, the optical sensitivities illustrated by way of example in the following table are multiplied by the shifts and/or rotations of the optical effective surface 29 that are caused by the resultant force Fᵣₑₛ and the resultant moment Mᵣₑₛ, and a sum for the optical effect of deflections of the mirror S3 is formed from the optical effects determined in this way.

| | | | Shift of the imaging in | | |
|---|---|---|---|---|---|
| | | | X | Y | Z |
| Disturbance | Amplitude | Unit | nm | nm | nm |
| Translational movement X | 1 | nm | −3.1 | 0 | 0 |
| Translational movement Y | 1 | nm | 0 | −3.2 | 0 |
| Translational movement Z | 1 | nm | 0 | 0 | −2.2 |
| Rotational movement RX | 1 | μrad | 0 | 255 | 20 |
| Rotational movement RY | 1 | μrad | 245 | 0 | 0 |
| Rotational movement RZ | 1 | μrad | 25 | 0 | 0 |

The optical effect, determined in this way, of deflections of the cooled mirror S3 is thus minimized by the adaptation of the forces FVTef, and here too the forces FVTef do not correspond to the local minimum of the individual regions 60, 61, 64 or to the minimized shift and/or rotation of the mirror S3 described in the previous method.

The optical effect can be determined, for example, via models on the basis of a pressure p acting in the supply line 57.1, 57.2 and in the fluid channel 51. The determination can be made at different pressures p, so that an optimum compromise for the configuration and arrangement of the supply lines 57.1, 57.2 can be found for all of the pressures investigated. This method can be carried out for each of the six mirrors S1, S2, S3, S4, S5, S6 in the example in FIG. 1.

In a further method, the reduction of the effects of flow-induced and transferred vibrations on the imaging quality of the projection exposure apparatus 1 (FIG. 1) is based on the optimization of the imaging quality of the projection optics unit 10 (FIG. 1).

The optimization of the individual mirrors S1, S2, S3, S4, S5, S6 can be adapted, as above even in the case of the reduction of the forces FVTef, such that the minimal parasitic optical effect is not set in consideration of the individual mirror S1, S2, S3, S4, S5, S6, but rather the projection optics unit 10 with the mirrors S1, S2, S3, S4, S5, S6 causes a minimal parasitic optical effect. The optical effects of deflections of the mirrors S1, S2, S3, S4, S5, S6 thus at least partially compensate for one another. The fundamentally symmetrical structure and/or the provision of the forces symmetrically with respect to the origin of the mirror coordinate system advantageously minimize them with an at least partial compensation. A convolution of the shifts and/or rotations of the mirror that were caused by the forces with the corresponding optical sensitivities minimizes the effect of the fluid-induced and transferred vibrations on the imaging quality of the projection exposure apparatus 1 yet again.

List of reference signs

| | |
|---|---|
| 1 | Projection exposure apparatus |
| 2 | Illumination system |
| 3 | Radiation source |
| 4 | Illumination optics unit |
| 5 | Object field |
| 6 | Object plane |
| 7 | Reticle |
| 8 | Reticle holder |
| 9 | Reticle displacement drive |
| 10 | Projection optics unit |
| 11 | Image field |
| 12 | Image plane |
| 13 | Wafer |
| 14 | Wafer holder |
| 15 | Wafer displacement drive |
| 16 | EUV radiation |
| 17 | Collector |
| 18 | Intermediate focal plane |
| 19 | Deflection mirror |
| 20 | Facet mirror |
| 21 | Facets |
| 22 | Facet mirror |
| 23 | Facets |
| 29 | Optical effective surface |
| 30 | Mirror module |
| 31 | Fluid channel |
| 32 | Fluid |
| 33 | Fluid channel inner surface |
| 34.1, 34.2 | Lever arm forces F_{AT2y}, F_{AT3y} |
| 35 | Inlet |
| 36 | Outlet |
| 37 | Feed line, discharge line |
| 39 | 90° elbow piece |
| 40 | Mirror module |
| 41 | Fluid channel |
| 42 | Fluid |
| 43 | Inner surface |
| 44 | Lever arm forces F_{AT1y}, F_{AT2y} |
| 45 | Inlet |
| 46 | Outlet |
| 47 | Feed line, discharge line |
| 48 | Bearing feed line, discharge line |
| 49 | 90° elbow piece |
| 50 | Mirror module |
| 51 | Fluid channel |
| 52 | Fluid |
| 53 | Inner surface |
| 54 | Lever arm forces F_{AT1y}, F_{AT2y} |
| 55 | Inlet |
| 56 | Outlet |
| 57 | Feed line, discharge line |
| 58 | Bearing feed line, discharge line |
| 59 | 90° elbow piece |
| 60 | Mirror region |
| 61 | Feed line region |
| 62 | Deflection region 1 |
| 63 | Deflection region 2 |
| 64 | Discharge line region |
| 65 | Bellows |
| 66 | Support frame |
| 101 | Projection exposure apparatus |
| 102 | Illumination system |
| 107 | Reticle |
| 108 | Reticle holder |
| 110 | Projection optics unit |
| 113 | Wafer |
| 114 | Wafer holder |
| 116 | DUV radiation |
| 117 | Optical element |
| 118 | Mounts |
| 119 | Lens housing |
| S1-S6 | Mirror |
| P | Pressure in the fluid channel |
| A_{T11x}, A_{T12x}, A_{T2x}, | Partial area of fluid channel inner surface |
| A_{T2y}, A_{T3x}, A_{T3y} | |
| P_{ef} | Force action points |
| F_{Atef} | Forces on the mirror |
| F_{VTef} | Forces on supply lines |
| F_{uw} | Pair of forces |
| Fᵣₑₛ | Resultant force |
| M_{VTef} | Moment on the mirror |
| M_{Atef} | Moment on supply line |
| Mᵣₑₛ | Resultant moment |

What is claimed is:

1. A projection exposure apparatus having at least one module,
wherein the module comprises a fluid channel configured to contain a pressurized fluid,
wherein the fluid channel is connected to supply lines,
wherein the supply lines are connected to a support frame via bearing points,
wherein the module is symmetrical,
wherein the fluid channel and the supply lines lie in a plane,
wherein the plane is perpendicular to a z-axis through a reference point, and
wherein the module is configured to rotate exclusively about the z-axis in response to parasitic forces and moments stemming from the pressurized fluid.

2. The projection exposure apparatus as claimed in claim 1,
wherein the supply lines run in the plane at least as far as the bearing points.

3. The projection exposure apparatus as claimed in claim 1,
wherein at least one decoupling element arranged in the supply lines is located within the plane.

4. The projection exposure apparatus as claimed in claim 3,
wherein at least two mutually perpendicular decoupling elements are located above attachments of the supply lines to the bearing points.

5. The projection exposure apparatus as claimed in claim 3,
wherein the at least one decoupling element is stiff in an axial direction and flexible in a lateral direction.

6. The projection exposure apparatus as claimed in claim 1,
wherein the module is decoupled from the bearing points in all six degrees of freedom.

7. The projection exposure apparatus as claimed in claim 1,
wherein the fluid channel and/or the supply lines are configured such that the parasitic forces and/or moments that are generated by the pressurized fluid are reduced within the module.

8. The projection exposure apparatus as claimed in claim 1,
wherein the fluid channel and/or the supply lines are configured such that a shift and/or rotation of the optical module caused by the parasitic forces and/or moments is reduced.

9. The projection exposure apparatus as claimed in claim 1,
wherein the fluid channels and/or the supply lines are configured such that the parasitic forces and/or moments are provided so that a parasitic optical effect of the optical module is reduced.

10. The projection exposure apparatus as claimed in claim 1,
wherein the fluid channels and/or the supply lines are configured such that the parasitic forces and/or moments are provided so that a parasitic optical effect of the projection optics unit is reduced.

11. The projection exposure apparatus as claimed in claim 1,
wherein the module is configured as an optical module.

12. The projection exposure apparatus as claimed in claim 1,
wherein the module is configured as a module for holding and positioning a wafer.

13. The projection exposure apparatus as claimed in claim 1,
wherein the module is configured as a component of the projection exposure apparatus.

14. The projection exposure apparatus as claimed in claim 13,
wherein the module is configured as a reference structure for positioning a mirror module.

15. The projection exposure apparatus as claimed in claim 1,
wherein the module has a symmetrical structure with respect to a reference point provided on the module.

16. A method for reducing an effect of parasitic forces and/or moments acting on a module of a projection exposure apparatus and caused by flow-induced pressure fluctuations or pressure fluctuations transferred via a fluid on imaging quality of the projection exposure apparatus, comprising:
determining the parasitic forces and/or moments,
defining at least two at least partially compensating forces and/or moments, and
configuring the module to generate the compensating forces and/or moments.

17. The method as claimed in claim 16,
wherein said configuring comprises arranging and/or aligning and/or selecting a material for at least one component of the module.

18. The method as claimed in claim 17,
wherein said configuring comprises arranging and/or aligning and/or selecting a material for at least one supply line and one fluid channel of the module.

19. The method as claimed in claim 16,
wherein the parasitic forces and/or moments are reduced for at least a partial region of the module.

20. The method as claimed in claim 16,
wherein the parasitic forces and/or moments are reduced for a module.

21. The method as claimed in claim 16,
wherein the module is configured as an optical module.

22. The method as claimed in claim 16,
wherein the module is configured as a module for holding and positioning a wafer.

23. The method as claimed in claim 16,
wherein a shift and/or rotation of the optical module caused by the parasitic forces and/or moments is reduced.

24. The method as claimed in claim 16,
wherein said determining comprises determining a parasitic optical effect of the optical module by multiplying a shift and/or a rotation of the optical module by corresponding optical sensitivities.

25. The method as claimed in claim 24,
wherein the parasitic forces and/or moments are provided such that a parasitic optical effect of the optical module is reduced.

26. The method as claimed in claim 25,
wherein the parasitic optical effects of at least one optical module are added to a parasitic optical effect of a projection optics unit of the projection exposure apparatus.

27. The method as claimed in claim 26,
wherein the parasitic forces and/or moments are provided such that the parasitic optical effect of the projection optics unit is reduced.
